(19) United States
(12) Patent Application Publication
(10) Pub. No.: US 2007/0102748 A1
(43) Pub. Date: May 10, 2007

(54) Gate electrode and MOS transistor including gate and method of fabricating the same

(75) Inventors: Uway Tseng, Taichung (TW); Yao-Hui Huang, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/269,582

(22) Filed: Nov. 9, 2005

(51) Int. Cl. H01L 21/336; H01L 29/76

(52) U.S. Cl. 257/314; 438/257

(57) ABSTRACT

A gate electrode. The gate electrode includes a substrate, a gate dielectric layer formed thereon, and a gate conductive layer comprising a stack of polysilicon grains formed on the gate dielectric layer, wherein the average size of the polysilicon grains decreases gradually in a direction away from the substrate. The invention also provides a metal oxide semiconductor (MOS) transistor including the gate and a method of fabricating the MOS transistor.

### BACKGROUND

The present invention relates to semiconductor manufacturing, and more specifically to a novel gate electrode and a metal oxide semiconductor (MOS) transistor including the gate.

Polysilicon is frequently used as a gate electrode in a metal oxide semiconductor (MOS) device. See S. Wolf, Silicon Processing for the VLSI Era, Volume 2—Process Integration, Lattice Press, 318-319 (1990) and U.S. Pat. No. 5,147,813 and U.S. Pat. No. 5,229,631 to Been-Jon Woo. As the width of polysilicon gate electrode is reduced to 0.18 μm and beyond, its height is reduced to 1500 Å and less, the morphology (e.g., silicon grain structure) of polysilicon layer becomes increasingly important in determining various characteristics of MOS devices.

FIG. 1 is a cross section of a conventional gate electrode. A gate dielectric layer 104 is formed on a substrate 102. A poly gate layer 106 comprising small silicon grains 108 is formed on the gate dielectric layer 104. After the gate electrode 100 is formed, dopants 110 are implanted into the poly gate layer 106 to reduce resistance thereof.

The dopants 110, however, easily enter the small silicon grains 108, resulting in serious grain distortion, greatly increasing stress 112 on the interface between the silicon grains 108 and substrate 102.

Generally, the dopants 110 are extremely small and have a very high diffusion coefficient in both silicon and gate dielectric materials at high temperatures. Thus, during subsequent high-temperature annealing, the dopants 110 may penetrate into and through the gate dielectric layer 104. With time, they may move further into the crystalline silicon substrate 102.

As the dopants 110 penetrate into the gate dielectric layer 104, drawbacks may occur, such as increased-gate leakage current and low carrier mobility, degrading device performance.

Additionally, the small silicon grains 108 occupy the bottom of the gate 106, resulting in strong interaction 112 between the silicon grains 108 and carriers 114, retarding drive current.

Thus, there exists a strong need in the art for a polysilicon layer structure which reduces stress between silicon grains and substrate and inhibits dopant penetration.

### SUMMARY

The invention provides a gate electrode comprising a substrate, a gate dielectric layer formed thereon, and a gate conductive layer comprising a stack of polysilicon grains formed on the gate dielectric layer, wherein the average size of the polysilicon grains decreases gradually in a direction away from the substrate.

The invention also provides a metal oxide semiconductor (MOS) transistor comprising a substrate, a gate dielectric layer formed thereon, a gate electrode comprising a stack of polysilicon grains formed on the gate dielectric layer, and a source/drain formed on both sides of the gate electrode in the substrate, wherein the average size of the polysilicon grains decreases gradually in a direction away from the substrate.

The invention further provides a method of fabricating the MOS transistor. A substrate is provided and a gate dielectric layer is formed thereon. A gate electrode comprising a stack of polysilicon grains is formed on the gate dielectric layer, wherein the average size of the polysilicon grains decreases gradually in a direction away from the substrate.

A detailed description is given in the following embodiment with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross section of a conventional gate electrode.

FIGS. 2A˜2E are cross sections of a method of fabricating a metal oxide semiconductor (MOS) transistor of an embodiment of the invention.

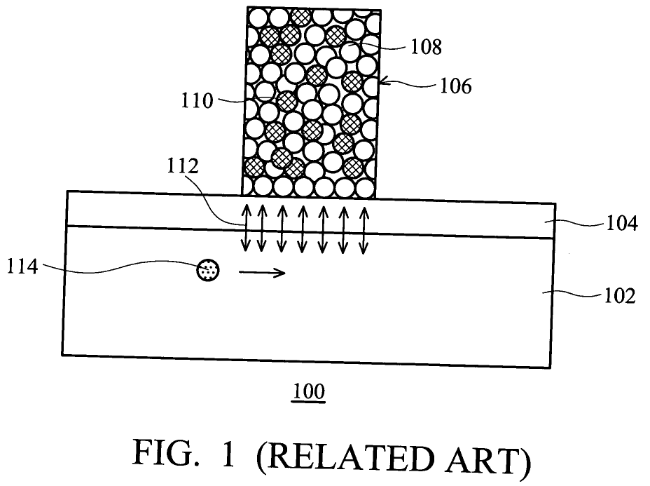

### DESCRIPTION

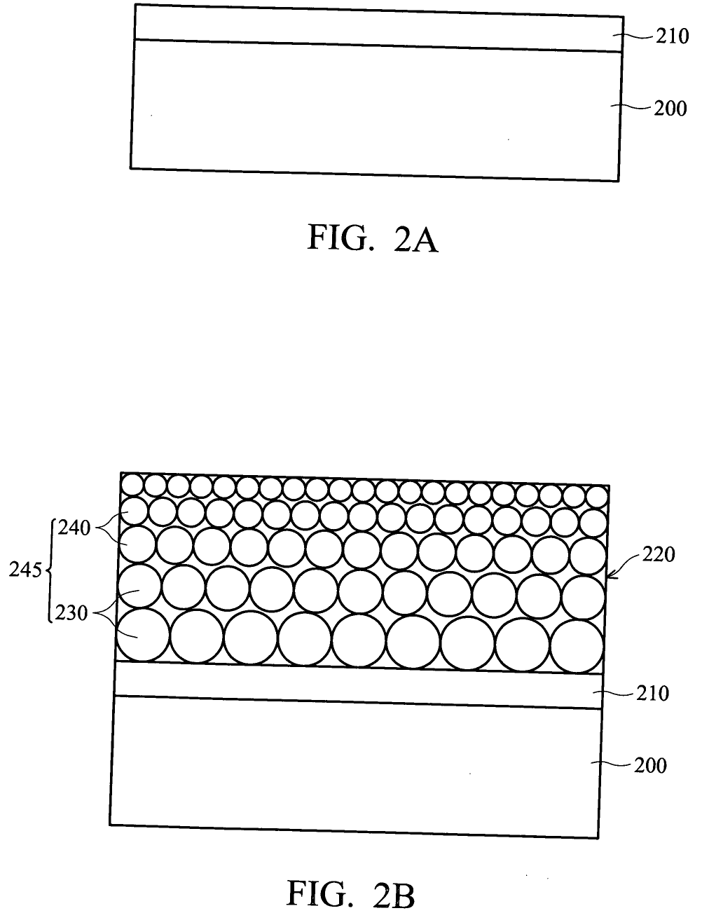

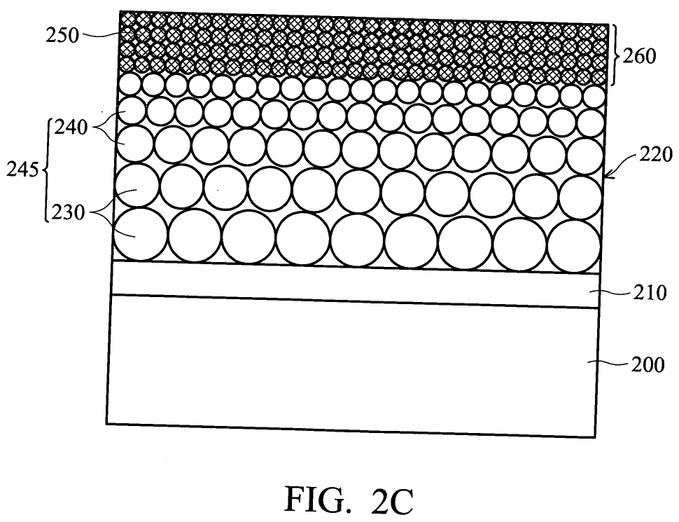

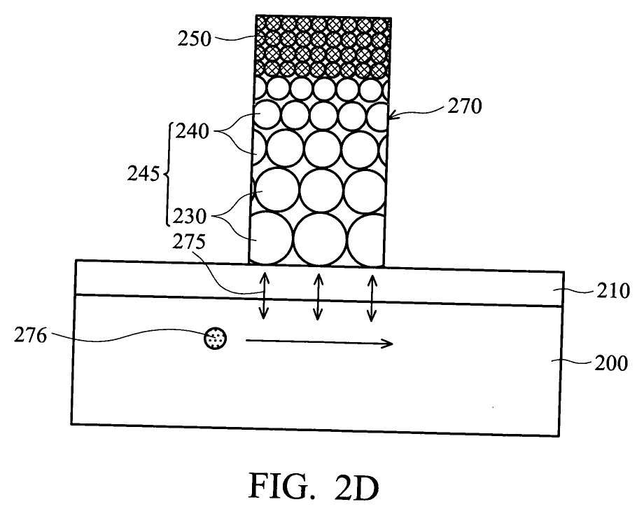

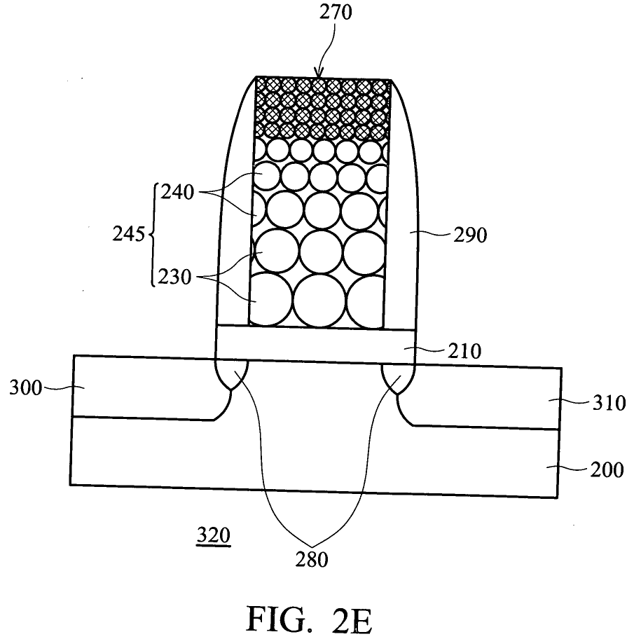

FIGS. 2A˜2E are cross sections of a method of fabricating a metal oxide semiconductor (MOS) transistor according to an embodiment of the invention.

Referring to FIG. 2A, a semiconductor substrate 200, such as P-type, N-type, or epitaxy silicon substrate, is provided and a gate dielectric layer 210 formed thereon typically by thermal oxidation. The gate dielectric layer 210 is preferably silicon oxide but may comprise silicon nitride or silicon oxynitride.

Referring to FIG. 2B, a gate conductive layer 220 comprising a stack of polysilicon grains is formed on the gate dielectric layer 210 by low pressure chemical vapor deposition (LPCVD) altering carrier gas flow rates with a decreasing gradient. The carrier gas may comprise any gases inert to silane, such as nitrogen, neon (Ne), and argon (Ar) gases. As carrier gas flow rate decreases, polysilicon grain size decreases commensurately, such that the larger grains 230 are closer to the substrate 200 than the smaller grains 240, that is, the average size of the polysilicon grains decreases gradually in a direction away 5 from the substrate 200.

The polysilicon grains 230 and 240 constitute a specific and regular arrangement 245 in which their sizes vertically gradually increase toward the substrate 200.

The specific polysilicon grain arrangement 245 can also be 10 formed by altering the processing temperature or pressure of the LPCVD. The processing temperature is altered with a decreasing gradient within a range from 600° C. to 500° C. and the pressure is altered with an increasing gradient within a range from 0.2 Torr to 1 Torr.

Next, dopants 250, such as boron atoms, are implanted into the gate conductive layer 220 and form a doped region 260 confined at the top of the gate conductive layer 220, as shown in FIG. 2C. The gate conductive layer 220 is then defined by isotropic dry etching, such as reactive ion etching (RIE), to form a gate structure 270, as shown in FIG. 2D.

The dopants 250 are blocked outside the polysilicon grains 230 and 240 due to the regular and dense grain arrangement 245, thereby releasing stress 275 on the interface between the polysilicon grains and the substrate 200 and effectively eliminating dopant penetration, thus reducing gate leakage current and increasing carrier mobility. Additionally, the larger polysilicon grains 230 occupy the bottom of the gate 270, resulting in less interaction 275 between the polysilicon grains 230 and carriers 276 due to decreased grain number, accelerating drive current.

Referring to FIG. 2E, doped ions are lightly implanted into both sides of the gate 270 in the substrate 200 to form a lightly doped drain (LDD) 280. Next, spacers 290 are formed along the laterals of the gate 270 by chemical vapor deposition (CVD) and anisotropic etching. Next, doped ions are heavy implanted into the outside of the lightly doped drain (LDD) 280 to form a source 300 and a drain 310. Accordingly, a metal oxide semiconductor (MOS) transistor 320 of the invention is achieved. The doped ions may comprise phosphorous or arsenic ions and the disclosed MOS transistor 320 comprises n-type MOS (NMOS) or p-type MOS (PMOS) transistor.

In the invention, the source 300, drain 310, and gate 270 may be silicided (not shown) to reduce resistance thereof.

The invention provides. a novel polysilicon grain arrangement of a gate conductive layer in which grain size vertically gradually increases toward the substrate, blocking doped atoms outside polysilicon grains. Indeed, experimental measurements show that stress on interface between polysilicon grains and substrate is dramatically reduced and dopant penetration eliminated simultaneously due to the absence of dopants in polysilicon grains. Additionally, carrier mobility can be increased due to reduced interaction between polysilicon grains and carriers, significantly improving device performance. Further, the formation of the gate conductive layer provided by the invention is simple, merely altered, such as carrier gas flow rate or processing temperature or pressure, of LPCVD, compatible with conventional MOS transistor fabrication.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A gate electrode, comprising:
a substrate;
a gate dielectric layer formed on the substrate; and
a gate conductive layer comprising a stack of polysilicon grains formed on the gate dielectric layer, wherein the average size of the polysilicon grains decreases gradually in a direction away from the substrate.

2. The gate electrode as claimed in 1, wherein the gate electrode has a width less than 0.09 μm.

3. The gate electrode as claimed in 1, further comprising a doped region confined at the top of the gate conductive layer.

4. The gate electrode as claimed in 3, wherein the doped atoms comprise boron atoms.

5. A metal oxide semiconductor (MOS) transistor, comprising:
a substrate;
a gate dielectric layer formed on the substrate;
a gate electrode comprising a stack of polysilicon grains formed on the gate dielectric layer, wherein the average size of the polysilicon grains decreases gradually in a direction away from the substrate; and
a source/drain formed on both sides of the gate electrode in the substrate.

6. The MOS transistor as claimed in 5, wherein the metal oxide semiconductor (MOS) transistor comprises an n-type metal oxide semiconductor (NMOS) transistor.

7. The MOS transistor as claimed in 5, wherein the metal oxide semiconductor (MOS) transistor comprises a p-type metal oxide semiconductor (PMOS) transistor.

8. The MOS transistor as claimed in 5, wherein the gate electrode has a width less than 0.09 μm.

9. The MOS transistor as claimed in 5, further comprising a doped region confined at the top of the gate electrode.

10. The MOS transistor as claimed in 9, wherein the doped atoms comprise boron atoms.

11. A method of fabricating a metal oxide semiconductor (MOS) transistor, comprising:
providing a substrate;
forming a gate dielectric layer on the substrate; and
forming a gate electrode comprising a stack of polysilicon grains on the gate dielectric layer, wherein the average size of the polysilicon grains decreases gradually in a direction away from the substrate.

12. The method as claimed in 11, wherein the gate electrode has a width less than 0.09 μm.

13. The method as claimed in 11, wherein the gate electrode is formed by low pressure chemical vapor deposition (LPCVD).

14. The method as claimed in 13, wherein a carrier gas flow rate is altered with a decreasing gradient in the low pressure chemical vapor deposition (LPCVD).

15. The method as claimed in 14, wherein larger polysilicon grains are formed by conducting higher carrier gas flow rate than the smaller ones.

16. The method as claimed in 14, wherein the carrier gas comprises nitrogen, neon (Ne), or argon (Ar) gas.

17. The method as claimed in 13, wherein a temperature is altered with a decreasing gradient within a range from 600° C. to 500° C. in the low pressure chemical vapor deposition (LPCVD).

18. The method as claimed in 17, wherein larger polysilicon grains are formed at higher temperature than the smaller ones.

19. The method as claimed in 13, wherein a pressure is altered with an increasing gradient within a range from 0.2 Torr to 1 Torr in the low pressure chemical vapor deposition (LPCVD).

20. The method as claimed in 19, wherein larger polysilicon grains are formed at lower pressure than the smaller ones.

21. The method as claimed in 11, further comprising forming a doped region confined at the top of the gate electrode.

22. The method as claimed in 21, wherein the doped atoms comprise boron atoms.
